(19) United States
(12) Patent Application Publication
(10) Pub. No.: US 2016/0064651 A1
(43) Pub. Date: Mar. 3, 2016

(54) METHOD TO MAKE THREE-TERMINAL MRAM

(71) Applicant: Yimin Guo, San Jose, CA (US)

(72) Inventor: Yimin Guo, San Jose, CA (US)

(73) Assignee: T3MEMORY, INC., Saratoga, CA (US)

(21) Appl. No.: 14/475,575

(22) Filed: Sep. 3, 2014

(51) Int. Cl. H01L 43/08; H01L 43/10; H01L 43/12; H01L 43/02

(52) U.S. Cl. CPC H01L 43/08; H01L 43/02; H01L 43/10; H01L 43/12

(57) ABSTRACT

This invention is about a method to make three-terminal spin transfer torque transistor magnetic random access memory (ST3-MRAM) cell using plasma based ion implantation. The core memory stack of such ST3-MRAM cell contains a bottom digit line (or VIA), a thick dielectric insulating layer, a memory layer, another thin dielectric layer, and a magnetic reference layer on the top. After the formation of the top magnetic reference pillar by photolithography patterning and etching, the outside region of the magnetic memory layer is converted to a non-magnetic conducting lead by heavy doping of boron ions generated by plasma from boron hydrogen (BxH3x) containing gas.

### RELATED APPLICATIONS

This application claims the priority benefit of U.S. Provisional Application No. 61/874,029 filed on Sep. 5, 2013, which is incorporated herein by reference.

### BACKGROUND OF THE INVENTION

1. Field of the Invention

This invention relates generally to a three terminal magnetic-random-access memory (MRAM) cell, more particularly to the method of fabricating three terminal MRAM memory elements.

2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can also cope with high-speed reading and writing. A ferromagnetic tunnel junction has a three-layer stack structure formed by stacking a recording layer having a changeable magnetization direction, an insulating tunnel barrier layer, and a fixed layer that is located on the opposite side from the recording layer and maintains a predetermined magnetization direction. Corresponding to the parallel and anti-parallel magnetic states between the recording layer magnetization and the reference layer magnetization, the magnetic memory element has low and high electrical resistance states, respectively. Accordingly, a detection of the resistance allows a magnetoresistive element to provide information stored in the magnetic memory device.

Typically, MRAM devices are classified by different write methods. A traditional MRAM is a magnetic field-switched MRAM utilizing electric line currents to generate magnetic fields and switch the magnetization direction of the recording layer in a magnetoresistive element at their cross-point location during the programming write. A spin-transfer torque (or STT)-MRAM has a different write method utilizing electrons' spin momentum transfer. Specifically, the angular momentum of the spin-polarized electrons is transmitted to the electrons in the magnetic material serving as the magnetic recording layer. According to this method, the magnetization direction of a recording layer is reversed by applying a spin-polarized current to the magnetoresistive element. As the volume of the magnetic layer forming the recording layer becomes smaller, the injected spin-polarized current to write or switch can be also smaller.

Besides a write current, the stability of the magnetic orientation in a MRAM cell as another critical parameter has to be kept high enough for a good data retention, and is typically characterized by the so-called thermal factor which is proportional to the energy barrier as well as the volume of the recording layer cell size.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus unintentionally reversing the direction of magnetization of the recording layer in MTJ.

Above issues or problems are all associated with the traditional two-terminal MRAM configuration. Thus, it is desirable to provide robust STT-MRAM structures and methods that realize highly-accurate reading, highly-reliable recording and low power consumption while suppressing destruction and reduction of life of MTJ memory device due to recording in a nonvolatile memory that performs recording resistance changes, and maintaining a high thermal factor for a good data retention.

It is known that perpendicular magnet (PM) spin transfer torque magnetic random access memory pSTT-MRAM) is an ideal memory for future semiconducting device. Current pSTT-MRAM is a two-terminal device with magnetic memory layer and reference layer separated by a thin MgO dielectric layer to form a so-called magnetic tunneling junction (MTJ). The shortcomings of such two-terminal pSTT-MRAM are its large critical write current and narrow current separation between read and write process. It has been recently reported that by applying a bias voltage across the MTJ junction with a right polarization could reduce coercivity (Hc) of the magnetic layer adjacent to the MgO layer. A so-called voltage-controlled pSTT-MRAM has been proposed [W.-G. Wang et al., Natural Materials, Vol. 11, 64, 2012].

### BRIEF SUMMARY OF THE PRESENT INVENTION

This invention is about a method to make three-terminal spin transfer torque transistor magnetic random access memory (ST3-MRAM) cell using plasma based ion implantation. The core memory stack of such ST3-MRAM cell contains a bottom digit line (or VIA), a thick dielectric insulating layer, a memory layer, another thin dielectric layer, and a magnetic reference layer on the top. After the formation of the top magnetic reference pillar by photolithography patterning and etching, the outside region of the magnetic memory layer is converted to a non-magnetic conducting lead by heavy doping of boron ions generated by plasma from boron hydrogen (BxH3x) containing gas.

The memory cell further includes a circuitry coupled to the bit line positioned adjacent to selected ones of the plurality of magnetoresistive memory elements to supply a reading current or bi-directional spin polarized current to the MTJ stack, and coupled to the digital line configured to generate an electric field on the functional layer and accordingly to decrease the switching energy barrier of the recording layer. Thus magnetization of a recording layer can be readily switched or reversed to the direction in accordance with a direction of a current across the MTJ stack by applying a low spin transfer current.

The exemplary embodiment will be described hereinafter with reference to the companying drawings. The drawings are schematic or conceptual, and the relationships between the thickness and width of portions, the proportional coefficients of sizes among portions, etc., are not necessarily the same as the actual values thereof.

### BRIEF DESCRIPTION OF THE DRAWINGS

FIG. 1 Schematics of a spin transfer torque transistor magnetic random access memory cell.

FIG. 2 Substrate with VIA connecting to the underneath CMOS control circuit.

FIG. 3 The core stack of the ST3-MRAM is deposited on the substrate

FIG. 4 The device wafer is patterned and etched to form a top magnetic reference pillar

FIG. 5 Boron plasma based ion implantation is used to form a memory region within the mask covered area.

FIG. 6 The top etched portion is refilled by dielectric material and flattened by CMP.

FIG. 7 A lead to the middle memory layer is formed by milling and metal refill.

### DETAILED DESCRIPTION OF THE INVENTION

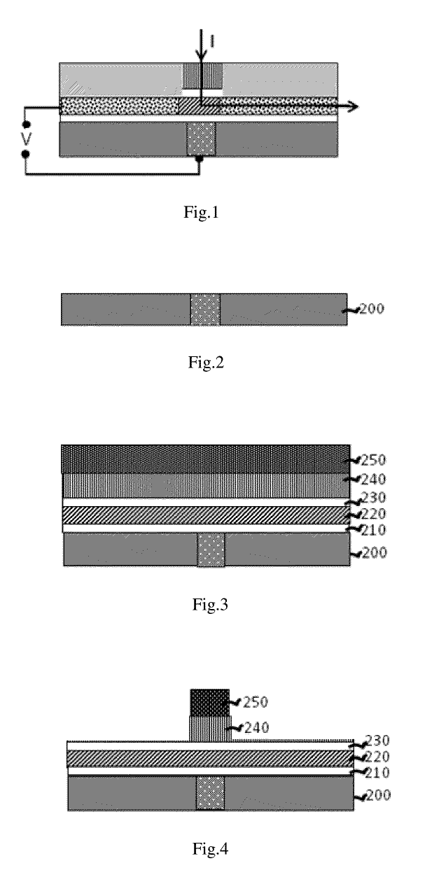

The three-terminal spin transfer torque transistor magnetic random access memory (ST3-MRAM) contains a digital line at the bottom, a bit line on the top, and a magnetic memory cell in the middle (FIG. 1). The middle memory cell has a bottom insulating layer (ILD), a magnetic memory layer, a dielectric MgO tunneling layer and a top magnetic reference layer. The top reference layer has perpendicular magnetization to the plane, and the polarization of the middle memory layer can be either perpendicular to the plane or in the plane depending on the voltage applied to the middle memory layer across the bottom ILD layer. Both read and write current flow through the top reference layer and middle memory layer. The digital line has a small contact area with the insulating layer below the memory cell which helps to reduce writing current when a voltage pulse is applied.

A device substrate (FIG. 2) contains a VIA (200) in the middle which is connected to the bottom CMOS control circuits already built in (not shown). Then TMR film stack is deposited on top of the VIA [FIG. 3], which contains ILD1 (210)/ML(220)/MgO(230)/PM(240)/Ta(250), where ILD1(210) is either a single MgO layer with a thickness of about 25 A, or bi-layer of 10Al2O3/20MgO. The MgO tunneling layer (230) has a thickness of 10-15 A. The ML (220) is a magnetic memory layer containing either CoFeB or bi-layer of CoFeB/CoFe, and PM (240) is a magnetic reference layer with its magnetization aligned perpendicular to the plane. A typical material used for PM is TbCo, CoPd, CoPt or super lattice of [Co/Pt]n, [Co/Pd]n, [Co/Ni]n. The top Ta layer (250) is a hard mask layer with a typical thickness of 200-400A.

A photolithography patterning and a subsequent reactive ion etching is used to form a small magnetic reference pillar. The etching is stopped on the top MgO layer (230 in FIG. 4) using Ta as a hard mask.

Then a boron plasma based ion implantation is used to add boron ions into the exposed memory layer. The source of the boron is from a boron hydrogen containing gas, BxH3x, such as BH3, B3H6, H3H9. In the plasma, boron become B− ion, which are accelerated by a bias voltage applied between the plasma and substrate and impinged into the memory layer (FIG. 5). By controlling the bias power and gas flow rate and chamber process pressure, appropriate amount of boron atoms can be implanted into the memory layer and completely convert it into a non-magnetic conducting layer after a high temperature anneal. We also can use normal ion implantation technique to add Li, Cu, Al, Ag, Au, Pt, and other metal atoms into the memory layer for the same purpose.

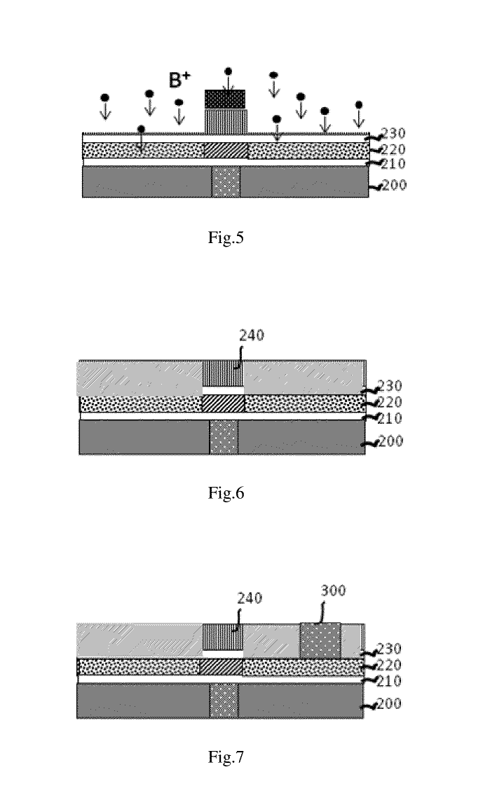

Then the milled portion of the reference layer and hard mask is refilled by a dielectric film such as SiO2 or SiNx, followed by a chemical mechanic polishing (CMP), the top surface of the memory cell become flat (FIG. 6).

With another photolithography patterning, milling and metal refill and CMP, a conducting lead (300) to the middle memory layer can be formed (FIG. 7).

Finally, the just formed three-terminal magnetic random access memory is annealed to repair damage film structure by ion implantation with an annealing temperature no less than 200° C. and an annealing time no less than half hour.

The memory operation can be seen from FIG. 1 that the top reference layer has perpendicular magnetization to the plane, and the polarization of the middle memory layer can be either perpendicular to the plane or in the plane depending on the voltage applied to the middle memory layer across the bottom ILD layer. Both read and write current flow through the top reference layer and middle memory layer. The bottom digital line has a small contact area with the insulating layer below the memory cell which helps to reduce writing current when a voltage pulse is applied.

1. A magnetic random access memory has three terminals;

2. The element of claim 1, wherein the three-terminal magnetic random access memory has its first electrode connected to the top magnetic reference layer, the second electrode connected to the middle memory layer, and the third electrode is underneath the bottom isolating layer pointing towards the middle memory cell;

3. The element of claim 1, wherein the three terminals magnetic random access memory contains a core film stack of bottom insulating layer (IL), a magnetic memory layer, a dielectric tunneling layer, a top magnetic reference layer;

4. The element of claim 3, wherein the magnetization of the top magnetic reference layer is perpendicular to the plane and magnetization of the memory layer is modulated by the voltage between the first and third electrode, which could be perpendicular to the plane or lie in the plane,

5. The element of claim 2, wherein both the write and read currents flow through the first and the second electrode, and the write current can be reduced by applying a voltage between the first and third electrode;

6. The element of claim 1, wherein the three terminals magnetic random access memory has a small footprint with its three terminal vertically overlaid and cross each other, and the size of the top pillar of the digital line is small and can create a high potential point during memory writing;

7. The element of claim 1, wherein the three-terminal spin transistor memory has a large metal base on top of the VIA connecting to the CMOS control circuit, with film stack of Ta/Ru or Cu & Al alloy/Ta with a thickness of 20-50Ta/200-400 Ru/100-200Ta;

8. The element of claim 3, wherein the memory cell has an insulating layer one (ILD), magnetic memory layer, a MgO tunneling layer, a magnetic reference layer, a capping layer and a hard mask layer;

9. The element of claim 8, wherein the memory insulating layer one (ILD) is a single MgO with a thickness between 10-30 A, or a bi-layer of Al2O3/MgO with a thickness range of AL2O3: 10-20 A, MgO:10-20 A;

10. The element of claim 8, wherein the magnetic memory layer is CoFeB: 10-20 A or CoFeB/CoFe with CoFe as interface dusting layer (2-5 A);

11. The element of claim 8, wherein the top magnetic reference layer is CoTb, CoPt, CoPd, or [Co/Pt]n, [Co/Ni]n [Co/Pd]n superlattice with a total thickness between 20-80 A;

12. The element of claim 8, wherein the hard mask layer of the core memory stack is Ta, or Ta alloy with a thickness between 100-400 A;

13. The element of claim 12, wherein a photolithography patterning and etching is used to form Ta small pillar hard mask using C, H, F containing chemical gas, such as CF4, CF3H;

14. The element of claim 13, wherein the formed Ta pillar is used as a hard mask and another etch using CH3OH or CO & NH4 is used to etch the exposed magnetic reference layer;

15. The element of claim 14, wherein plasma based ion implantation is used to add Boron ions into the memory layer using B, H containing gas source (BxH3x), such as BH3, B2H6, B6H9;

16. The element of claim 15, wherein the device wafer is positively biased to accelerate B− ions to impinge into the memory layer

17. The element of claim 14, wherein a normal ion implantation can also be used to add metallic atoms into the memory layer using Li, Al, Cu, Ag, Au, Pt or other metals;

18. The element of claim 14, wherein the etched hard mask area is filled with SiO2 OR SiN and CMPed to flatten the surface;

19. The element of claim 19, wherein another photolithography patterning, etching and metal refill is used to form a VIA to provide a conducting lead for the middle memory layer;

20. The element of claim 1, wherein the three-terminal magnetic random access memory is finally annealed to repair damage film structure by ion implantation with an annealing temperature no less than 200° C. and an annealing time no less than half hour.
